(19) United States
(12) Patent Application Publication
(10) Pub. No.: US 2006/0089000 A1
(43) Pub. Date: Apr. 27, 2006

(54) Material and process for etched structure filling and planarizing

(75) Inventors: Ronald A. Della Guardia, Poughkeepsie, NY (US); Ranee Kwong, Wappingers Falls, NY (US); Wenjie Li, Poughkeepsie, NY (US); Qinghuang Lin, Yorktown Heights, NY (US); Dirk Pfeiffer, Dobbs Ferry, NY (US); David L. Rath, Stormville, NY (US)

Correspondence Address: Intellectual Property Law;IBM Corporation, Dept. 18G, Building 300-482, 2070 Route 52, Hopewell Junction, NY, 12533, US

(73) Assignee: International Business Machines Corporation, Armonk, NY (US)

(21) Appl. No.: 10/973,683

(22) Filed: Oct. 26, 2004

(51) Int. Cl. H01L 21/461; C09K 13/00; H01L 21/302

(52) U.S. Cl. 438/692; 252/79.1; 438/694

(57) ABSTRACT

In the back end of integrated circuits employing low-k interlevel dielectrics, etched structures are filled with a planarizing material comprising a cyclic olefin polymer and solvent; the next pattern to be etched is defined in a photosensitive layer above the planarizing layer; the pattern is etched in the dielectric and the planarizing material is stripped in a wet process that does not damage the interlevel dielectric.

### TECHNICAL FIELD

The field of the invention is integrated circuit fabrication, in particular fabricating interconnection structures in the portion of the circuit known as the back end, and more specifically in depositing a planarizing material; defining the next pattern to be etched in a photosensitive layer above the planarizing material; etching the pattern in the dielectric and stripping the planarizing material.

### BACKGROUND OF THE INVENTION

Several basic methods for forming a dual damascene structure have been developed for the purpose of connecting vertically separated conductors in the portion of the process that connects up individual transistors to form a circuit, referred to as the back end of the line (BEOL). These include the via-first approach, the line-first approach, and various hardmask schemes. All of these methods are fraught with problems.

An approach to forming successive layers in the back end that has the advantage of successfully eliminating poisoning of the photoresist is through the application of multilayer hardmask films such as oxide (SiO₂), nitride (Si₃N₄) and metal nitrides such as TaN. This concept was first described in U.S. Pat. No. 6,140,226 to Grill et al., and was used successfully by R. D. Goldblatt et al. (High Performance 0.13 Copper BEOL Technology with Low-k Dielectric, Proceedings of the IEEE 2000 International Interconnect Technology Conference, pp. 261-263) to pattern SiLK™ (low-k polyarylene ether dielectric). SiLK™ is a registered trademark of the Dow Chemical Company.

These methods are complex and can be difficult for Reactive Ion Etch (RIE) manufacturing, because the RIE must be able to etch the dielectric with high selectivity to the hardmask materials. That in turn may constrain the conditions under which the RIE may operate, and hence may compromise the ability to achieve the desired patterning control in the dielectric film. In the case of a non-silicon material containing organic polymers such as SiLK™, this is not as difficult to achieve and may be the preferred approach. However, in the case of Si-containing dielectric materials such as SiCOH, it is difficult to obtain high etch selectivity to any common hardmask materials, including metal nitrides. It becomes necessary to modify the conventional RIE chemistries or thicken the hardmask layers to the point where SiCOH pattern integrity is lost.

The line-first approach of defining vertical connections between levels of interconnection suffers from the difficulty of printing vias inside lines, especially at small dimensions. The reason for this difficulty is that the via imaging layer must be planarized above a variety of line trench patterns at different pattern densities, leading to variation in this imaging layer thickness in various structures. Because of the very small depth of focus of modern lithographic tools, it becomes difficult or impossible to define a photolithographic dose and focus process window that can image simultaneously all vias in all line pattern situations. As the via becomes ever smaller in size, it becomes ever more difficult to expose and develop a via image through the extra thickness of resist that fills in, and becomes planar over, the line structure.

The approaches mentioned above were developed and refined to deal with a particular problem of poisoning the photoresist by chemicals from lower layers, but generally describe a problem in the back end of advanced circuits—that the depth of focus of steppers is so small that it is necessary to deposit a planarizing material to provide a substantially planar surface within the depth of focus.

After the image has been defined in the photoresist and the image has been transferred to the interlevel dielectric (and to various barrier layers and cap layers associated with low-k materials) the planarizing material is stripped.

In the prior art, the stripping has been done by RIE because the planarizing materials are highly cross-linked or require such an aggressive strip. It has been discovered that a RIE strip causes significant damage to interlevel dielectrics.

Some alternative materials such as non-cross-linked polyhydroxy styrene (PHS) can be removed by a wet process, but cannot stand the temperature required for a low temperature oxide (LTO) or other material deposition processes because of its low glass-forming temperature (Tg). This and other similar materials tend to flow, blister or crack in the higher temperatures.

Thus, the requirements for a planarizing material—that it: a) withstand the temperature of a low temperature oxide deposition (>150° C.); b) have a Tg >150° C. and no material loss before 200° C. in a TGA (Thermo Gravimetric Analyzer) measurement; c) is removed by a RIE process that simultaneously removes a portion of the Interlayer Dielectric (ILD); and d) that the process of stripping the residual planarizing material does not damage the ILD; have not been met in the prior art.

The art could benefit from the provision of a planarizing material and method of applying it that performs the task of the planarizing material, is compatible with the ILD patterning process and can be stripped without damaging the ILD.

### SUMMARY OF THE INVENTION

The invention relates to a method of patterning an ILD layer in the back end of integrated circuit fabrication in which a planarizing layer is deposited over an ILD; an oxide layer is deposited over the planarizing layer; a photosensitive layer is deposited over the planarizing layer; the planarizing layer is patterned along with the ILD; and the residue of the planarizing layer is stripped in a wet process that does not damage the ILD.

A feature of the invention is the combination of an acidic polynorbornene polymer with a safe solvent such as propylene glycol monomethyl ether acetate (PGMEA).

Another feature of the invention is that the planarization material according to the invention can withstand the deposition of low temperature oxide (at >150° C.).

Yet another feature of the invention is that the planarization material has a Tg of greater than 150° C.

Yet another feature of the invention is that the planarization material is soluble in both organic solvents and aqueous base photoresist developer.

Yet another feature of the invention is that the planarization material comprises a cyclic olefin polymer, the cyclic olefin polymer comprising cyclic olefin units having an acidic moiety.

### BRIEF DESCRIPTION OF THE DRAWINGS

FIG. 1 shows a portion of an integrated circuit having a pair of vias etched into the ILD before the application of the planarizing layer.

FIG. 2 shows the same portion with the planarizing layer, a low temperature oxide layer and a layer of photoresist.

FIG. 3 shows the result of patterning and etching through the planarizing layer to produce a line connecting the two vias.

FIG. 4 shows the result of stripping the planarizing material.

FIG. 5 shows a diagram of a material according to the invention.

FIGS. 6A and 6B show diagrams of examples of material according to the invention.

FIG. 6C shows a table of properties of the two materials in FIGS. 6A and 6B.

### DETAILED DESCRIPTION

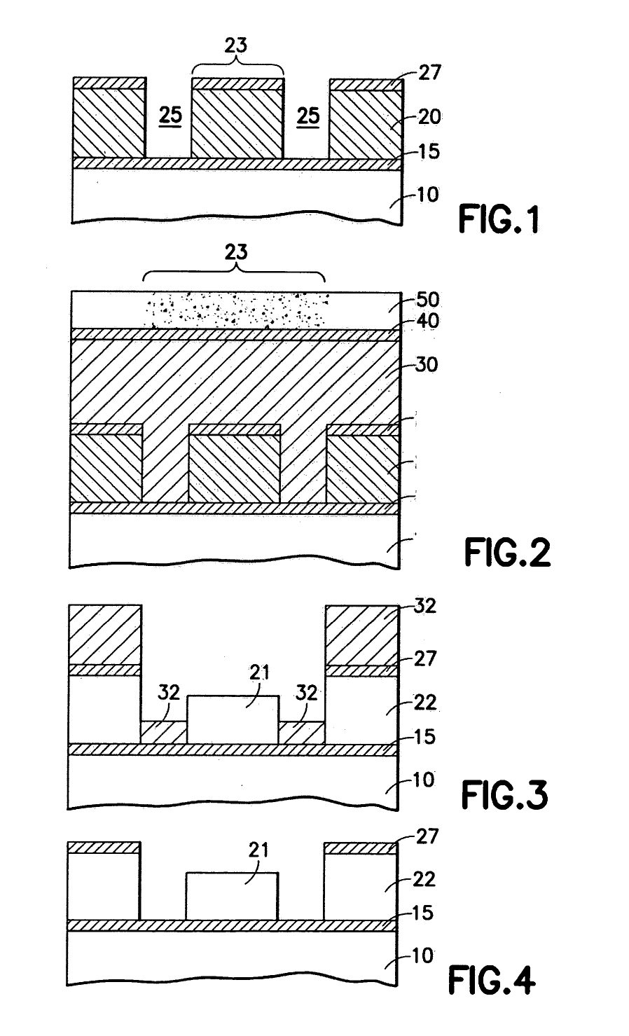

FIG. 1 shows a portion of the back end of an integrated circuit that will serve as the basis for application of the invention. At the bottom of the Figure, block 10 indicates schematically the integrated circuit substrate and lower levels of interconnect in the back end.

In the step shown as an example, a pair of vias 25 have been etched through low-k interlevel dielectric 20, stopping on cap layer 15. For example, cap layer 15 is TaN and the dielectric 20 is SiLK or SICOH. Those skilled in the art will be aware that other materials could be used.

At the top of FIG. 1, tetraethyl ortho-silicate (TEOS) layer 27 has been deposited to protect the dielectric.

Those skilled in the art are aware that modern optical steppers used in photo-lithography have a very limited depth of focus. It is known to deposit a planarizing layer to improve the planarity of the structure and to bring the relevant portions of the top layer within the depth of focus of the stepper.

FIG. 2 shows the result of depositing planarizing layer 30, filling the vias 25 and depositing a layer having a nominal thickness of 1000-2000 Angstroms above the TEOS cap layer. The thickness of this layer will be determined by the need to isolate and cover the alignment marks or other structures in lower layers and also to improve planarity.

A oxide layer 40 has been deposited with a nominal depth of 80 nm above the planarizing layer 30. A photoresist layer 50 (including an optional anti-reflection layer) has been deposited above the oxide and has been patterned in a region denoted with bracket 23. This region will be the site of an etch that will open a connection extending left-right in the Figure that connects vias 25.

Photoresist 50 is developed, forming a aperture having the width of bracket 23. Oxide layer 40 is removed at the bottom of the aperture, using any convenient technique.

A conventional dry etch is performed through the planarizing material down to TEOS layer 27 and through TEOS layer 27, using the same chemistry. The etch then continues, removing the portion of dielectric 20 within the aperture and also, simultaneously, the planarizing material.

FIG. 3 shows the result of this step, in which portion 21 of layer 22 has been lowered to permit deposition of a metal interconnect between the two vias and there is a residual amount of planarizing material 30 shown as portions 32 above the left and right, both outside the aperture, and in the bottom of the aperture.

The etching chemistry will be changed as required to remove any remaining oxide layer 40, and the planarizing material 30.

The inventors have discovered that the conventional RIE strip chemistry used in the prior art caused extensive damage to the dielectric 20 that gave rise to problems in the final circuit.

The prior art planarizing materials such as crosslinked PHS, were selected for durability in withstanding the effects of the high temperature associated with the deposition of the oxide. Cross linked polymers were used, which required aggressive stripping methods. These stripping methods, in turn, caused the damage to the dielectric.

According to the invention, a set of planarizing materials referred to generally as acidic cyclic olefin polymers has been developed that can be stripped in a wet process, such as organic solvents and/or an aqueous base developer, conventionally used for developing photoresist.

FIG. 4 shows the result of stripping the residual amount of the planarizing material 32, with the vias connected by a horizontal passage. Conventional barrier layers to confine a copper interconnect material, adhesion layers and cap layers are shown schematically as the lines of the lower portion of the apertures.

Cap layer 15 may or may not be removed, depending on the conductivity of the layer and the requirements of the circuit.

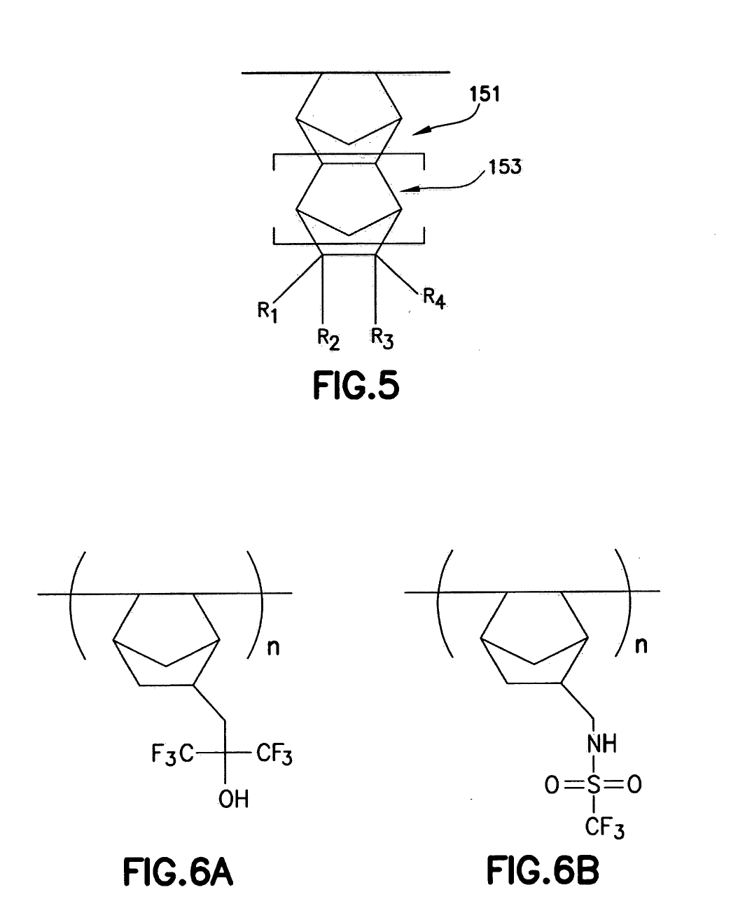

FIG. 5 shows a structure used in forming the planarizing material. According to the invention, the acidic cyclic olefin polymers used for planarizing materials are selected from a polymer comprising cyclic olefin units having the structure shown in FIG. 5 wherein R₁ to R₄ independently represent hydrogen and a linear or branched alkyl group with 1 to 10 carbon atoms, with the proviso that at least one of R₁ to R₄ contains at least one acidic moiety; t is an integer from 0 to 3.

Examples of the acidic moieties include hexafluoroalcohol, trifluoroalcohol, fluorosulfonamide, carboxylic acid, anhydride and the like.

At the top, numeral 151 denotes the portion of the monomer that connects to other monomers to form the polymer. The next portion down, denoted with the numeral 153 and set off by horizontal brackets and having the subscript t is an optional portion of the material. The value of t may be from 0 to 3; i.e. there may be no groups of this type or as many as three of them.

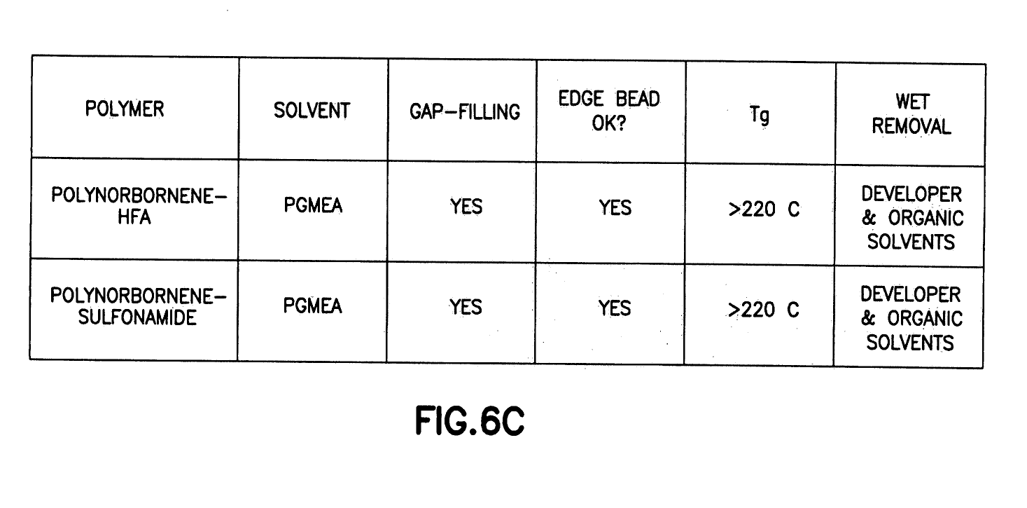

Two examples of this class of compounds are shown in FIGS. 6A and 6B.

FIG. 6A shows a symbol for polynorbornene hexafluoroalcohol (HFA), in which the acidic moiety is hexafluoroalcohol.

FIG. 6B shows a symbol for polynorbornene sulfonamide, in which the acidic moiety is fluorosulfonamide.

Both polynorbornene hexafluoroalcohol and polynorbornene sulfonamide polymers have glass transition temperatures (Tg) higher than 200° C. They are also thermally stable and do not show weight loss under TGA up to 300° C.

Thus, they can withstand the subsequent oxide deposition. These polymers have good solubilities in both organic solvents such as propylene glycol monomethyl ether acetate (PGMEA), ethyl lactate (EL), gamma-butyrolactone (GBL), ethyl ethoxy propionate, and cyclohexanone and aqueous base developer such as 0.26N tetramethyl ammonium hydroxide (TMAH). Therefore, they can be easily removed by these solvents in the wet stripping process.

FIG. 6C show a table listing some relevant properties of these two examples. The term safe solvents is commonly used in the field and includes PGMEA, EL and others such as GBL.

While the invention has been described in terms of a single preferred embodiment, those skilled in the art will recognize that the invention can be practiced in various versions within the spirit and scope of the following claims.

What is claimed is:

1. A method of patterning a layer in an integrated circuit having a recess in an interlevel dielectric comprising the steps of:
filling said recess with a planarizing material and depositing said planarizing material above said interlevel dielectric;
depositing a layer of oxide above said planarizing material;
depositing and patterning a photosensitive material above said layer of oxide;
etching with a reactive ion etch said planarizing material and said interlevel dielectric, leaving a residual amount of said planarizing material; and
stripping said residual amount of said planarizing material in a wet process.

2. A method according to claim 1, in which said layer of oxide is deposited at a temperature of greater than 150° C.

3. A method according to claim 1, in which said wet process comprises the use of at least one organic solvent.

4. A method according to claim 1, in which said wet process comprises the use of at least one base developer.

5. A method according to claim 2, in which said planarizing material is an acidic cyclic olefin polymer having a glass transition temperature greater than 150° C.

6. A method according to claim 1, in which said planarizing material is mixed with a safe solvent before said step of filling said recess.

7. A method according to claim 2, in which said planarizing material is mixed with a safe solvent before said step of filling said recess.

8. A method according to claim 5, in which said planarizing material is mixed with a safe solvent before said step of filling said recess.

9. A method according to claim 1, in which said planarizing material comprises a cyclic olefin polymer, said cyclic olefin polymer comprising cyclic olefin units having at least one acidic moiety.

10. A method according to claim 9, in which said planarizing material is mixed with a safe solvent before said step of filling said recess.

11. A method according to claim 9, in which said planarizing material includes at least one acidic moiety selected from the group comprising:
hexafluoroalcohol, trifluoroalcohol, fluorosulforamide, carboxylic acid and anhydride.

12. A method according to claim 9, in which said planarizing material comprises a polynorbornene polymer.

13. A method according to claim 9, in which said planarizing material is soluble in an organic solvent.

14. A method according to claim 9, in which said planarizing material is soluble in a base developer.

15. A method according to claim 1, in which said planarizing material is selected from a polymer comprising cyclic olefin units having the following structure: 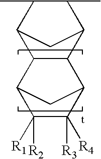
Wherein R₁ to R₄ independently represent hydrogen or a linear or branched alkyl group with 1 to 10 carbon atoms; and at least one of R₁ to R₄ contains at least one acidic moiety; and t is an integer from 0 to 3.

16. A method according to claim 15, in which said planarizing material includes at least one-acidic moiety selected from:
hexafluoroalcohol, trifluoroalcohol, fluorosulforamide, carboxylic acid and anhydride.

17. A method according to claim 15, in which said layer of oxide is deposited at a temperature of greater than 150° C.

18. A method according to claim 15, in which said planarizing material comprises a polynorbornene polymer.

19. A method according to claim 15, in which said planarizing material is an acidic cyclic olefin polymer having a glass transition temperature greater than 150° C.

20. A method according to claim 15, in which said planarizing material is soluble in an organic solvent.

21. A method according to claim 15, in which said planarizing material is soluble in a base developer.

22. A composition of matter comprising a polymer comprising cyclic olefin units having the following structure: 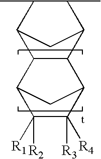
Wherein R₁ to R₄ independently represent hydrogen or a linear or branched alkyl group with 1 to 10 carbon atoms; at least one of R₁ to R₄ contains at least one acidic moiety; and t is an integer from 0 to 3.

23. A composition of matter according to claim 22, in which said polymer is a polynorbornene polymer.

24. A composition of matter according to claim 22, in which said acidic moiety is selected from the group comprising:
hexafluoroalcohol, trifluoroalcohol, fluorosulforamide, carboxylic acid and anhydride.
